(19) United States
(12) Patent Application Publication
(10) Pub. No.: US 2026/0113891 A1
(43) Pub. Date: Apr. 23, 2026

(54) Adjustable Heat Sink Holder Assembly for Cooling the Front Portion of a High Power Optics Plug Device in an Outdoor Conduction Cooled Network System

(71) Applicant: Ciena Corporation, Hanover, MD (US)

(72) Inventors: Chander Prakash Gupta, Gurugram (IN); Ranjeet Chaurasiya, Gurugram (IN); Shubham Kumar, Gurugram (IN); Rampratap Mahawar, Gurugram (IN)

(21) Appl. No.: 18/969,398

(22) Filed: Dec. 5, 2024

(30) Foreign Application Priority Data
Oct. 23, 2024 (IN) 202411080600

(51) Int. Cl. H05K 7/20

(52) U.S. Cl. CPC H05K 7/20545; H05K 7/207

(57) ABSTRACT

An adjustable heat sink holder assembly including a heat spreader plate adapted to be disposed adjacent to and in thermal communication with a plug device, where the heat spreader plate includes a main body portion adapted to be disposed adjacent to a central portion of the plug device and thermally condition the central portion of the plug device and an extension portion adapted to be disposed adjacent to a front end portion of the plug device and thermally condition the front end portion of the plug device. The plug device may be a high power optics plug device, with the central portion including digital signal processor hardware and the front end portion including an integrated coherent transmit-receive optical sub-assembly. In some embodiments, the heat spreader plate and the plug device are disposed in a sealed housing of an outdoor conduction cooled network system.

### TECHNICAL FIELD

The present disclosure relates generally to the telecommunications and optical networking fields. More particularly, the present disclosure relates to an adjustable heat sink holder assembly for cooling the front portion of a high power optics plug device, including an associated digital coherent optics (DCO) integrated coherent transmit-receive optical sub-assembly (IC-TROSA), in an outdoor conduction cooled network system.

### BACKGROUND

High power coherent optics transceiver plugs are widely used and provide network flexibility and programmability by supporting different baud rates and modulation formats. These high power coherent optics transceiver plugs use IC-TROSA blocks for coherent transmission as an optical sub-assembly combining the elements of a coherent optical front end with the associated control circuitry. The IC-TROSA’s miniaturized efficiency enables small form factor DCO transceivers in a QSFP or OSFP format, with the standard DCO coming in a CFP2 form factor, for example.

The IC-TROSA block generally consumes around 7-12W of power, with the high power coherent optics transceiver plug consuming around 20-30W of total power. This is significant power with respect to total power. Referring to FIG. 1, to handle the high power consuming IC-TROSA block 104, various QSFP plugs 100 and formats utilize an extended front end 102 where the IC-TROSA block 104 is disposed. A heat sink 106 is often provided at and integrated into the extended front end 102 of the QSFP plugs 100. A similar arrangement is used for OSFP plugs and formats.

Referring to FIG. 2, in an air cooled network system 200, the plugs 100 are inserted into corresponding optics cages 202 within the module housing 201. The heat sink 106 provided at and integrated into the extended front end 102 of each plug 100 and the associated IC-TROSA block 104 remain outside of the porous faceplate 204 of the air cooled network system 200, such that the heat sink 106 is exposed to the air flow through the porous faceplate 204. Further, a heat sink 206 may be disposed adjacent to each optics cage 202 within the module housing 201 and exposed to the air flow through the air cooled network system 200 to cool the central body 108 of each plug 100 as the air flow is drawn through the porous faceplate 204 and the module housing 201 via a plurality of fan assemblies 208 disposed at the back of the module housing 201, for example.

In an outdoor conduction cooled network system, however, there may be no fan assemblies and no external air flow, as such network systems may be substantially sealed. Thus, a different mechanism is required to cool (or heat) the extended front end of each plug and the associated IC-TROSA block when high power coherent optics transceiver plugs are used.

The present background is provided as environmental context only. It will be readily apparent to those of ordinary skill in the art that the principles and concepts of the present disclosure may be implemented in other environmental contexts equally, without limitation.

### SUMMARY

The present disclosure provides an adjustable heat sink holder assembly for cooling the front portion of a high power optics plug device, including an associated DCO IC-TROSA, in an outdoor conduction cooled network system. The outdoor conduction cooled network system (or other substantially sealed network system) includes a module housing in which a heat spreader plate is disposed to cool (or heat) the central bodies of each of one or more plugs, including the digital signal processor (DSP) hardware, when the one or more plugs are inserted into one or more cages adjacent to the heat spreader plate. The heat spreader plate may serve to cool (or heat) the central bodies of each of one or more plugs, including the DSP hardware, via a thermally coupled thermoelectric cooler (TEC) that may be operated in either a cooling mode or a heating mode and/or a vapor chamber (VC). The one or more cages may be coupled to a printed circuit board (PCB) opposite the heat spreader plate and TEC/VC within the module, however this is not required.

The heat spreader plate includes an extension portion that protrudes from the heat spreader plate corresponding to the front end of each of the one or more plugs extending from the one or more cages. Thus, this extension portion of the heat spreader plate corresponds to the IC-TROSA of each of the one or more plugs, serving to effectively cool (or heat) the IC-TROSA of each of the one or more plugs in the outdoor conduction cooled network system (or other substantially sealed network system) for which the use of air flow cooled IC-TROSA heat sinks is not otherwise available.

The extension portions of the heat spreader plate each include one or more adjustable thermal contact surfaces that are adapted to engage corresponding surfaces of the front ends of the respective plugs when the plugs are inserted into the cages. In this manner, the one or more adjustable thermal contact surfaces essentially surround the IC-TROSAs of the plugs, serving to thermally couple them to the extensions portions of the heat spreader plate and the bulk of the heat spreader plate itself.

The adjustable heat sink holder assembly may be used for cooling with ambient temperatures of +60 degrees C as well as for heating with subzero ambient temperatures, by changing the polarity of the TEC to provide the desired operating temperature range for the IC-TROSA(s) and DSP hardware of the plug(s) and module as a whole. Advantageously, the extension portion(s) that protrude(s) from the heat spreader plate help to prevent temperature variation between the IC-TROSA(s) and the DSP hardware that could lead to deleterious temperature (and/or rate) imbalances and optics damage, thereby enhancing optics life.

In some embodiments, the present disclosure provides a heat sink assembly including a heat spreader plate adapted to be disposed adjacent to and in thermal communication with a plug device, where the heat spreader plate includes a main body portion adapted to be disposed adjacent to a central portion of the plug device and thermally condition the central portion of the plug device and an extension portion adapted to be disposed adjacent to a front end portion of the plug device and thermally condition the front end portion of the plug device. The heat sink assembly may further include a thermoelectric cooler disposed adjacent to and in thermal communication with the heat spreader plate and adapted to be operated in one of a cooling mode and a heating mode. The heat sink assembly may further include a vapor chamber defined by the heat spreader plate. In some embodiments, the extension portion of the heat spreader plate includes a lower extension portion adapted to be disposed adjacent to a lower front end portion of the plug device. In some embodiments, the lower extension portion includes a thermally conductive compressible pad covered by a protective plate that are collectively adapted to contact the lower front end portion of the plug device. In some embodiments, the extension portion of the heat spreader plate includes side extension portions adapted to be disposed adjacent to side front end portions of the plug device. In some embodiments, each of the side extension portions includes a thermally conductive compressible pad covered by a protective plate that are collectively adapted to contact the side front end portions of the plug device. The plug device may be a high power optics plug device, the central portion of the high power optics plug device may include digital signal processor hardware, and the front end portion of the high power optics plug device may include an integrated coherent transmit-receive optical sub-assembly. In some embodiments, the heat spreader plate and the plug device are disposed in a sealed housing of an outdoor conduction cooled network system.

In some embodiments, the present disclosure provides a network system including a sealed housing and a heat spreader plate disposed within the sealed housing and adapted to be disposed adjacent to and in thermal communication with a plug device also disposed within the sealed housing, where the heat spreader plate includes a main body portion adapted to be disposed adjacent to a central portion of the plug device and thermally condition the central portion of the plug device and an extension portion adapted to be disposed adjacent to a front end portion of the plug device and thermally condition the front end portion of the plug device. The network system may further include a thermoelectric cooler disposed adjacent to and in thermal communication with the heat spreader plate and adapted to be operated in one of a cooling mode and a heating mode. The network system may further include a vapor chamber defined by the heat spreader plate. In some embodiments, the extension portion of the heat spreader plate includes a lower extension portion adapted to be disposed adjacent to a lower front end portion of the plug device. In some embodiments, the lower extension portion includes a thermally conductive compressible pad covered by a protective plate that are collectively adapted to contact the lower front end portion of the plug device. In some embodiments, the extension portion of the heat spreader plate includes side extension portions adapted to be disposed adjacent to side front end portions of the plug device. In some embodiments, each of the side extension portions includes a thermally conductive compressible pad covered by a protective plate that are collectively adapted to contact the side front end portions of the plug device. The plug device may be a high power optics plug device, the central portion of the high power optics plug device may include digital signal processor hardware, and the front end portion of the high power optics plug device may include an integrated coherent transmit-receive optical sub-assembly. The heat spreader plate and the plug device may be disposed in the sealed housing of an outdoor conduction cooled network system.

In some embodiments, the present disclosure provides a heat sink method including providing a heat spreader plate disposed adjacent to and in thermal communication with a plug device, where the heat spreader plate includes a main body portion disposed adjacent to a central portion of the plug device and thermally conditioning the central portion of the plug device and an extension portion disposed adjacent to a front end portion of the plug device and thermally conditioning the front end portion of the plug device, and providing a thermoelectric cooler disposed adjacent to and in thermal communication with the heat spreader plate. The heat sink method further includes operating the thermoelectric cooler in one of a cooling mode to cool the central portion of the plug device and the front end portion of the plug device and a heating mode to heat the central portion of the plug device and the front end portion of the plug device.

It will be readily apparent to those of ordinary skill in the art that aspects and features of each of the described embodiments may be incorporated, omitted, and/or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 illustrates various QSFP plugs and front end IC-TROSA and heat sink arrangements;

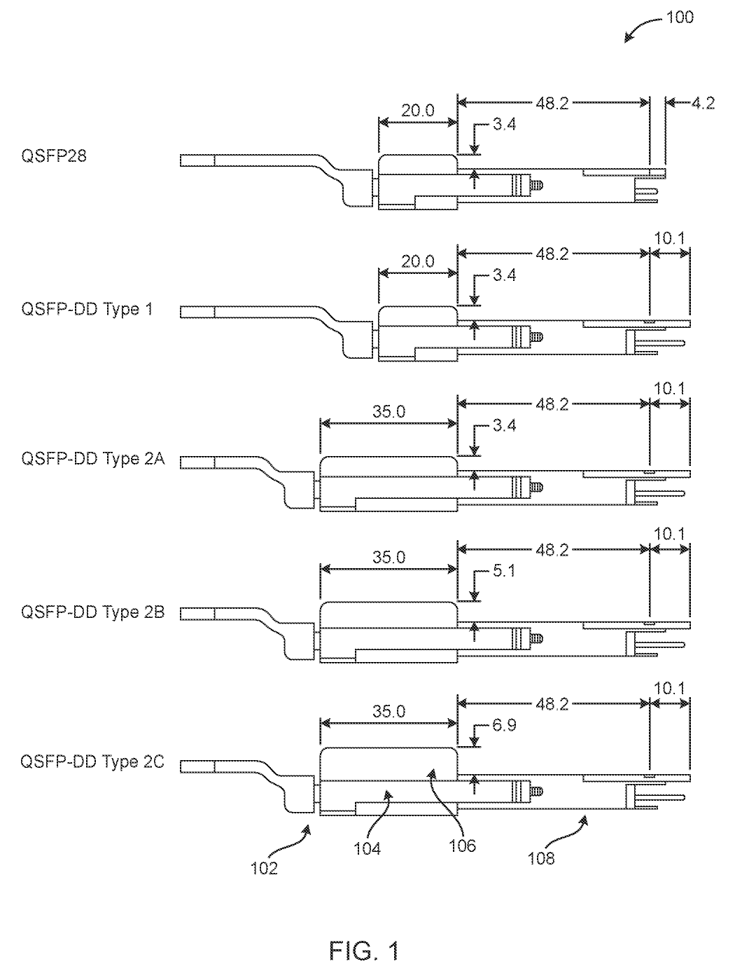

FIG. 2 illustrates an air cooled network system utilizing plug cooling via heat sinks, fan assemblies, and provided air flow;

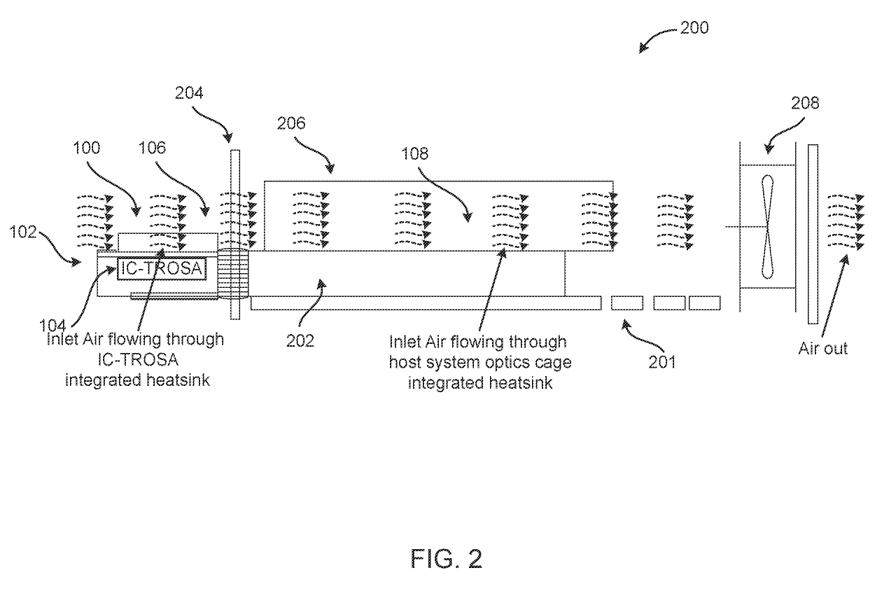

FIG. 3 illustrates an embodiment of the outdoor conduction cooled network system utilizing an embodiment of the adjustable heat sink holder assembly of the present disclosure;

FIG. 4 also illustrates an embodiment of the outdoor conduction cooled network system utilizing an embodiment of the adjustable heat sink holder assembly of the present disclosure;

FIG. 5 further illustrates an embodiment of the adjustable heat sink holder assembly of the present disclosure;

FIG. 6 still further illustrates an embodiment of the adjustable heat sink holder assembly of the present disclosure;

FIG. 7 still further illustrates an embodiment of the adjustable heat sink holder assembly of the present disclosure;

FIG. 8 still further illustrates an embodiment of the adjustable heat sink holder assembly of the present disclosure;

FIG. 9 still further illustrates an embodiment of the adjustable heat sink holder assembly of the present disclosure;

FIG. 10 still further illustrates an embodiment of the adjustable heat sink holder assembly of the present disclosure;

FIG. 11 still further illustrates an embodiment of the adjustable heat sink holder assembly of the present disclosure;

FIG. 12 illustrates an example of the thermal performance of the adjustable heat sink holder assembly of the present disclosure; and

FIG. 13 illustrates an embodiment of the plug cooling/heating method of the present disclosure in an outdoor conduction cooled network system.

It will be readily apparent to those of ordinary skill in the art that aspects and features of each of the illustrated embodiments may be incorporated, omitted, and/or combined as desired in a given application, without limitation.

### DETAILED DESCRIPTION

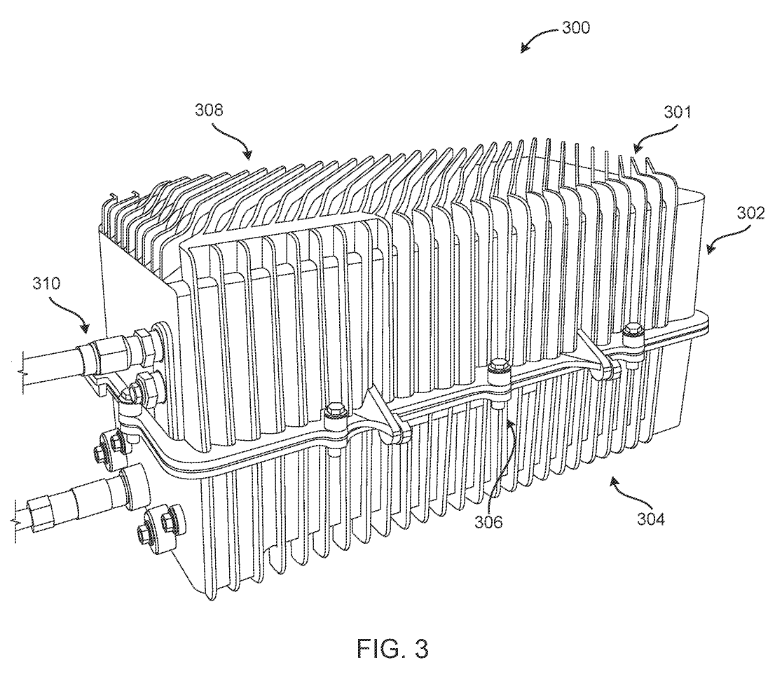

Referring to FIG. 3, again, the present disclosure provides an adjustable heat sink holder assembly for cooling the front portion of a high power optics plug device, including an associated DCO IC-TROSA, in an outdoor conduction cooled network system 300. The outdoor conduction cooled network system 300 (or other substantially sealed network system) includes a module housing 301 in which the adjustable heat sink holder assembly is disposed. The module housing 301 of the outdoor conduction cooled network system 300 typically includes an upper lid 302 that is secured to a lower tray 304 via a plurality of securement mechanisms 306, such as screws, fasteners, clips, etc., to form a substantially sealed enclosure for containing the adjustable heat sink holder assembly and other components of the outdoor conduction cooled network system 300. Due to the substantially sealed nature of the module housing 301, external-to-internal air flow is not available to condition the components of the outdoor conduction cooled network system 300 and conduction is primarily relied upon. The outside surfaces of the module housing 301 may include any number and configuration of protruding structures, 308, such as fins, pins, etc., for increasing the external conduction surface of the module housing 301. Appropriate external-to-internal connections may be made to the components of the outdoor conduction cooled network system 300 via one or more cables passing through the upper lid 302 and/or lower tray 304 of the module housing 301. It will be understood by those of ordinary skill in the art that all stated spatial relationships are relative and can be rotated as desired in a given application, such that upper and lower or top and bottom become left and right, first and second, etc. Accordingly, such stated spatial relationships are not intended to be limiting in any manner, stating only relative position in a convenient manner as depicted in the various drawings.

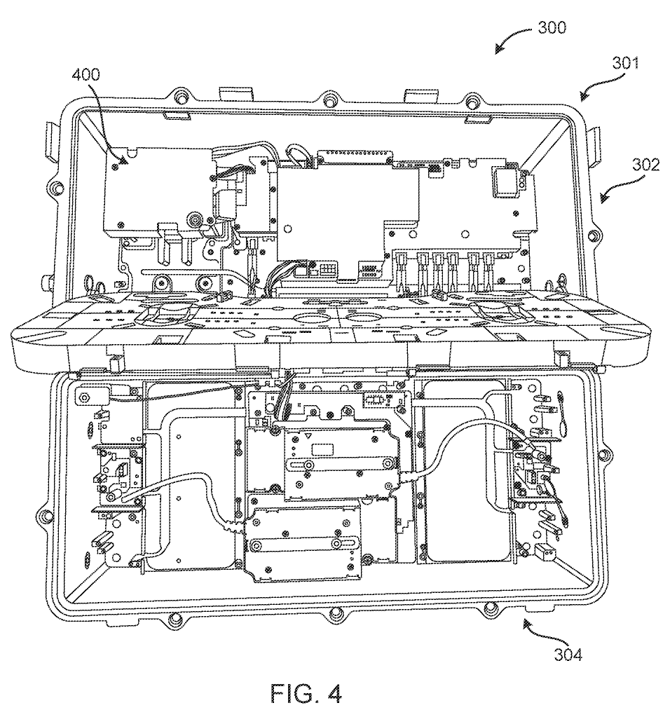

Referring to FIG. 4, the adjustable heat sink holder assembly 400 for cooling the front portion of a high power optics plug device, including the associated DCO IC-TROSA, is disposed within the module housing 301, such as within the upper lid 302 of the module housing 301, of the outdoor conduction cooled network system 300.

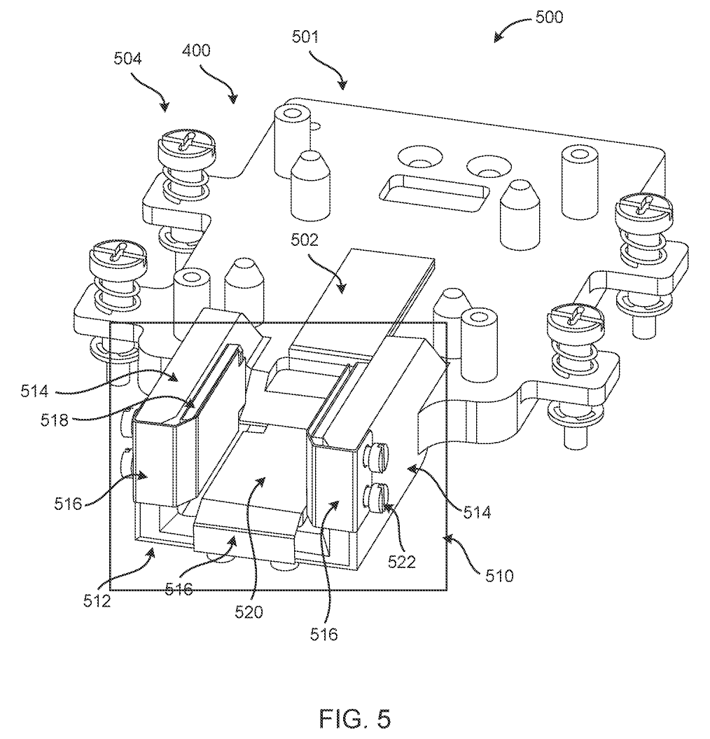

Referring to FIG. 5, the adjustable heat sink holder assembly 400 includes the heat spreader plate 500 including a main body portion 501 that is disposed to cool (or heat) the central bodies of each of the one or more plugs, including the DSP hardware, when the one or more plugs are inserted into the one or more cages adjacent to the heat spreader plate 500. The heat spreader plate may serve to cool (or heat) the central bodies of each of the one or more plugs, including the DSP hardware, via the thermally coupled TEC that may be operated in either a cooling mode or a heating mode and/or a VC. The one or more cages may be coupled to a PCB opposite the heat spreader plate 500 and TEC/VC within the module housing 301, however this is not required.

As provided, a single high power coherent optics transceiver plug is received within a single cage coupled to a PCB or other structure within the module housing 301. The heat spreader plate 500 of the adjustable heat sink holder assembly 400 is disposed adjacent to the cage opposite the PCB or other structure, with a pedestal structure 502 of the heat spreader plate 500 making thermal contact with the plug through the cage. This pedestal structure 502 may include a thermal interface material (TIM) coating or the like. The pedal structure 502 and the main body portion 501 of the heat spreader plate 500 are designed to cool (or heat) the DSP hardware in the main portion of the plug. The heat spreader plate 500 may be secured over the TEC and/or otherwise secured to the module housing 301 by any number and type of spring loaded screws 504 and/or other fasteners. These aspects are not central to the present disclosure and the adjustable heat sink holder assembly 400 and outdoor conduction cooled network system 300 may include any components not specifically detailed here.

The heat spreader plate 500 includes the extension portion 510 that protrudes from the heat spreader plate 500 corresponding to the front end of the plug extending from the cage. Thus, this extension portion 510 of the heat spreader plate 500 corresponds to the IC-TROSA disposed at the front end of the plug, serving to effectively cool (or heat) the IC-TROSA disposed at the front end of the plug in the outdoor conduction cooled network system 300 (or other substantially sealed network system) for which the use of air flow cooled IC-TROSA heat sinks is not otherwise available. The extension portion 510 of the heat spreader plate 500 includes a lower extension portion or floor 512 and side extension portions or walls 514 that are disposed about the front end of the plug and the IC-TROSA.

The extension portions 512,514 of the heat spreader plate 500 each include an adjustable thermal contact surface 516 that is adapted to slidingly engage the corresponding surface of the front end of the plug when the plug is inserted through the extension portions 512,514 of the heat spreader plate 500 and into the cage. In this manner, the adjustable thermal contact surfaces 516 essentially surround the IC-TROSA of the plug, serving to thermally couple the IC-TROSA to the extension portion 510 of the heat spreader plate 500 and the main body portion 501 of the heat spreader plate 500 itself. Each of the adjustable thermal contact surfaces 516 includes a graphite-over-foam (GoF) pad 518 that is covered by a protective member 520 against which the plug slides. The GoF pads 518 are compressible and the protective members 520 are imparted with a degree of movement via shoulder screws 522 that couple the protective members 520 to the extension portions 512,514 of the heat spreader plate 500. Thus, the extension portion 510 of the heat spreader plate 500 has a degree of tolerance for receiving the plug, while maintaining good thermal contact between the heat spreader plate 500, the extension portions 512,514, the adjustable thermal contact surfaces 516, and the IC-TROSA of the plug. Although a three-sided extension portion 510 is illustrated, a four-sided extension portion 510 could be used equally.

As mentioned above, the adjustable heat sink holder assembly 400 may be used for cooling with ambient temperatures of +60 degrees C as well as for heating with subzero ambient temperatures, by changing the polarity of the TEC to provide the desired operating temperature range for the IC-TROSA(s) and DSP hardware of the plug(s) and module 400 as a whole. Advantageously, the extension portion(s) 510 that protrude(s) from the heat spreader plate 500 help to prevent temperature variation between the IC-TROSA(s) and the DSP hardware that could lead to deleterious temperature (and/or rate) imbalances and optics damage, thereby enhancing optics life.

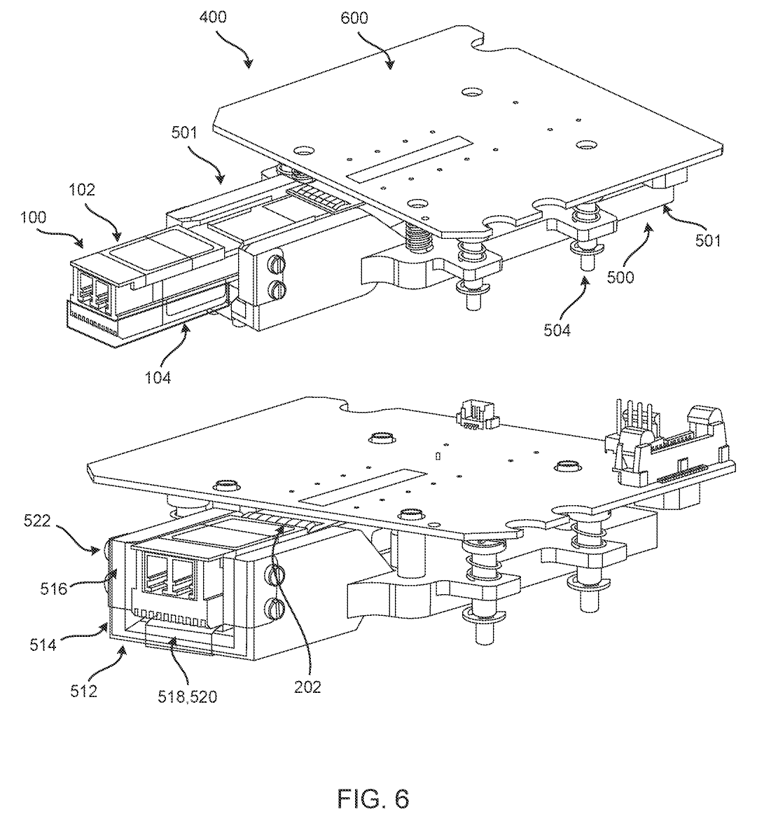

Referring to FIG. 6, again, the adjustable heat sink holder assembly 400 includes the main body portion 501 of the heat spreader plate 500 that is disposed to cool (or heat) the central bodies of each of the one or more plugs 100, including the DSP hardware, when the one or more plugs 100 are inserted into the one or more cages 202 adjacent to the heat spreader plate 500. The heat spreader plate may serve to cool (or heat) the central bodies of each of the one or more plugs 100, including the DSP hardware, via the thermally coupled TEC that may be operated in either a cooling mode or a heating mode and/or a VC. The one or more cages 202 may be coupled to the PCB 600 opposite the heat spreader plate 500 and TEC/VC within the module housing 301, however this is not required.

As provided, a single high power coherent optics transceiver plug 100 is received within a single cage 202 coupled to the PCB 600 or other structure within the module housing 301. The heat spreader plate 500 of the adjustable heat sink holder assembly 400 is disposed adjacent to the cage opposite the PCB 600 or other structure, with a pedestal structure 502 of the heat spreader plate 500 making thermal contact with the plug 100 through the cage 202. This pedestal structure 502 may include the TIM coating or the like. The pedal structure 502 and the main body portion 501 of the heat spreader plate 500 are designed to cool (or heat) the DSP hardware in the main portion of the plug 100. The heat spreader plate 500 may be secured over the TEC and/or otherwise secured to the module housing 301 by any number and type of spring loaded screws 504 and/or other fasteners. These aspects are not central to the present disclosure and the adjustable heat sink holder assembly 400 and outdoor conduction cooled network system 300 may include any components not specifically detailed here.

The heat spreader plate 500 includes the extension portion 510 that protrudes from the heat spreader plate 500 corresponding to the front end 102 of the plug 100 extending from the cage 202. Thus, this extension portion 510 of the heat spreader plate 500 corresponds to the IC-TROSA 104 disposed at the front end 102 of the plug 100, serving to effectively cool (or heat) the IC-TROSA 104 disposed at the front end 102 of the plug 100 in the outdoor conduction cooled network system 300 (or other substantially sealed network system) for which the use of air flow cooled IC-TROSA heat sinks is not otherwise available. The extension portion 510 of the heat spreader plate 500 includes a lower extension portion 512 and side extension portions 514 that are disposed about the front end 102 of the plug 100 and the IC-TROSA 104.

The extension portions 512,514 of the heat spreader plate 500 each include the adjustable thermal contact surface 516 that is adapted to slidingly engage the corresponding surface of the front end 102 of the plug 100 when the plug 100 is inserted through the extension portions 512,514 of the heat spreader plate 500 and into the cage 202. In this manner, the adjustable thermal contact surfaces 516 essentially surround the IC-TROSA 104 of the plug 100, serving to thermally couple the IC-TROSA 104 to the extension portion 510 of the heat spreader plate 500 and the bulk of the heat spreader plate 500 itself. Each of the adjustable thermal contact surfaces 516 includes the GoF pad 518 that is covered by the protective member 520 against which the plug 100 slides. The GoF pads 518 are compressible and the protective members 520 are imparted with a degree of movement via the shoulder screws 522 that couple the protective members 520 to the extension portions 512,514 of the heat spreader plate 500. Thus, the extension portion 510 of the heat spreader plate 500 has a degree of tolerance for receiving the plug 100, while maintaining good thermal contact between the heat spreader plate 500, the extension portions 512,514, the adjustable thermal contact surfaces 516, and the IC-TROSA 104 of the plug 100. Although a three-sided extension portion 510 is illustrated, a four-sided extension portion 510 could be used equally.

As mentioned above, the adjustable heat sink holder assembly 400 may be used for cooling with ambient temperatures of +60 degrees C as well as for heating with subzero ambient temperatures, by changing the polarity of the TEC to provide the desired operating temperature range for the IC-TROSA(s) 104 and DSP hardware of the plug(s) 100 and module 400 as a whole. Advantageously, the extension portion(s) 510 that protrude(s) from the heat spreader plate 500 help to prevent temperature variation between the IC-TROSA(s) 104 and the DSP hardware that could lead to deleterious temperature (and/or rate) imbalances and optics damage, thereby enhancing optics life.

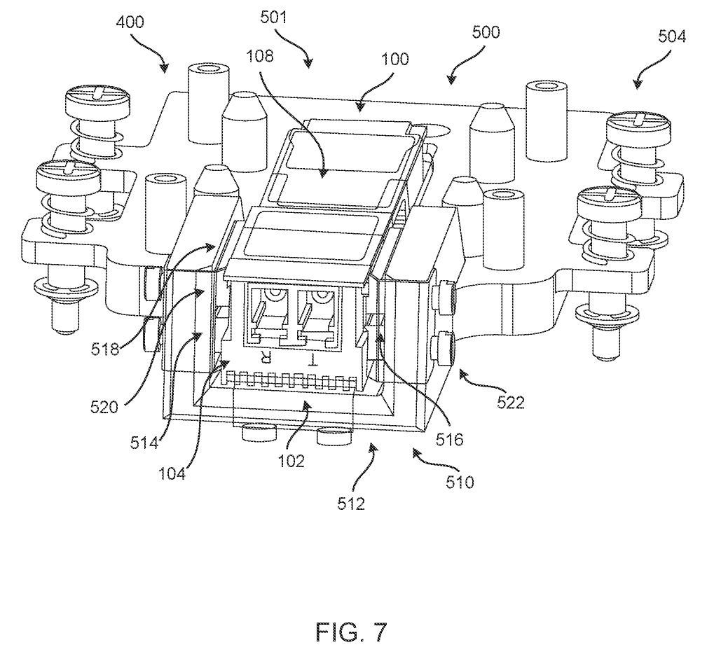

Referring to FIG. 7, again, the adjustable heat sink holder assembly 400 includes the heat spreader plate 500 that is disposed to cool (or heat) the central bodies 108 of each of the one or more plugs 100, including the DSP hardware, when the one or more plugs 100 are inserted into the one or more cages 202 adjacent to the heat spreader plate 500. The heat spreader plate may serve to cool (or heat) the central bodies 108 of each of the one or more plugs 100, including the DSP hardware, via the thermally coupled TEC that may be operated in either a cooling mode or a heating mode and/or a VC. The one or more cages 202 may be coupled to the PCB 600 opposite the heat spreader plate 500 and TEC/VC within the module housing 301, however this is not required.

As provided, a single high power coherent optics transceiver plug 100 is received within a single cage 202 coupled to the PCB 600 or other structure within the module housing 301. The heat spreader plate 500 of the adjustable heat sink holder assembly 400 is disposed adjacent to the cage opposite the PCB 600 or other structure, with a pedestal structure 502 of the heat spreader plate 500 making thermal contact with the plug 100 through the cage 202. This pedestal structure 502 may include the TIM coating or the like. The pedal structure 502 and the bulk of the heat spreader plate 500 are designed to cool (or heat) the DSP hardware in the main portion of the plug 100. The heat spreader plate 500 may be secured over the TEC and/or otherwise secured to the module housing 301 by any number and type of spring loaded screws 504 and/or other fasteners. These aspects are not central to the present disclosure and the adjustable heat sink holder assembly 400 and outdoor conduction cooled network system 300 may include any components not specifically detailed here.

The heat spreader plate 500 includes the extension portion 510 that protrudes from the heat spreader plate 500 corresponding to the front end 102 of the plug 100 extending from the cage 202. Thus, this extension portion 510 of the heat spreader plate 500 corresponds to the IC-TROSA 104 disposed at the front end 102 of the plug 100, serving to effectively cool (or heat) the IC-TROSA 104 disposed at the front end 102 of the plug 100 in the outdoor conduction cooled network system 300 (or other substantially sealed network system) for which the use of air flow cooled IC-TROSA heat sinks is not otherwise available. The extension portion 510 of the heat spreader plate 500 includes a lower extension portion 512 and side extension portions 514 that are disposed about the front end 102 of the plug 100 and the IC-TROSA 104.

The extension portions 512,514 of the heat spreader plate 500 each include the adjustable thermal contact surface 516 that is adapted to slidingly engage the corresponding surface of the front end 102 of the plug 100 when the plug 100 is inserted through the extension portions 512,514 of the heat spreader plate 500 and into the cage 202. In this manner, the adjustable thermal contact surfaces 516 essentially surround the IC-TROSA 104 of the plug 100, serving to thermally couple the IC-TROSA 104 to the extension portion 510 of the heat spreader plate 500 and the bulk of the heat spreader plate 500 itself. Each of the adjustable thermal contact surfaces 516 includes the GoF pad 518 that is covered by the protective member 520 against which the plug 100 slides. The GoF pads 518 are compressible and the protective members 520 are imparted with a degree of movement via the shoulder screws 522 that couple the protective members 520 to the extension portions 512,514 of the heat spreader plate 500. Thus, the extension portion 510 of the heat spreader plate 500 has a degree of tolerance for receiving the plug 100, while maintaining good thermal contact between the heat spreader plate 500, the extension portions 512,514, the adjustable thermal contact surfaces 516, and the IC-TROSA 104 of the plug 100. Although a three-sided extension portion 510 is illustrated, a four-sided extension portion 510 could be used equally. Here, the transmit and receive ports 802 of the plug 100 may also be seen.

As mentioned above, the adjustable heat sink holder assembly 400 may be used for cooling with ambient temperatures of +60 degrees C as well as for heating with subzero ambient temperatures, by changing the polarity of the TEC to provide the desired operating temperature range for the IC-TROSA(s) 104 and DSP hardware of the plug(s) 100 and module 400 as a whole. Advantageously, the extension portion(s) 510 that protrude(s) from the heat spreader plate 500 help to prevent temperature variation between the IC-TROSA(s) 104 and the DSP hardware that could lead to deleterious temperature (and/or rate) imbalances and optics damage, thereby enhancing optics life.

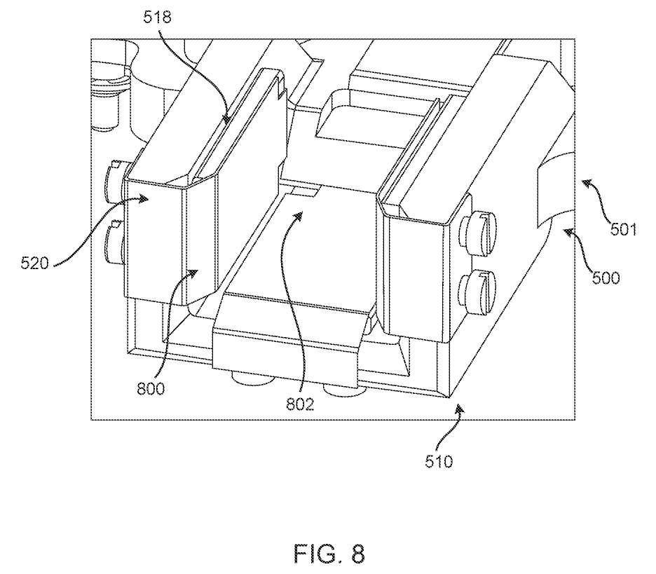

Referring to FIG. 8, the GoF pads 518 are covered by the loosely fitted, thin (~0.25mm thick) metal protective plates 520 that protect the GoF pads 518 from wear as the plug 100 is inserted into and removed from the cage 202, with the front end 102 of the plug 100 making thermal contact with the extended portion 510 of the heat spreader plate 500. These protective plates 520 may each include a chamfer feature 800 at a front edge thereof for promoting such relative sliding engagement, as the front end 102 of the plug 100 may include irregular and/or rough portions. The protective plates 520 may each also include a chamfer feature 802 at a rear edge thereof.

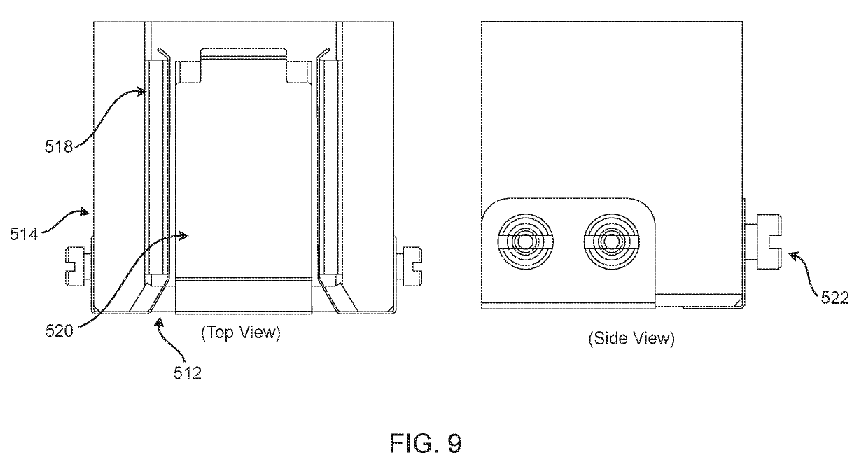

Referring to FIG. 9, each protective plate 520 is retained via a plurality of retention screws 522 disposed on an outboard side of the associated extension portion 512,514. These retention screws 522 provide each protective plate with a small degree of outboard play or movement, on the order of 1mm. This allows the front end 102 and IC-TROSA 104 of the plug 100 to be inserted between the protective plates 520 relatively easily, but while maintaining a desired thermal contact pressure through the protective plates 520 and GoF pads 518.

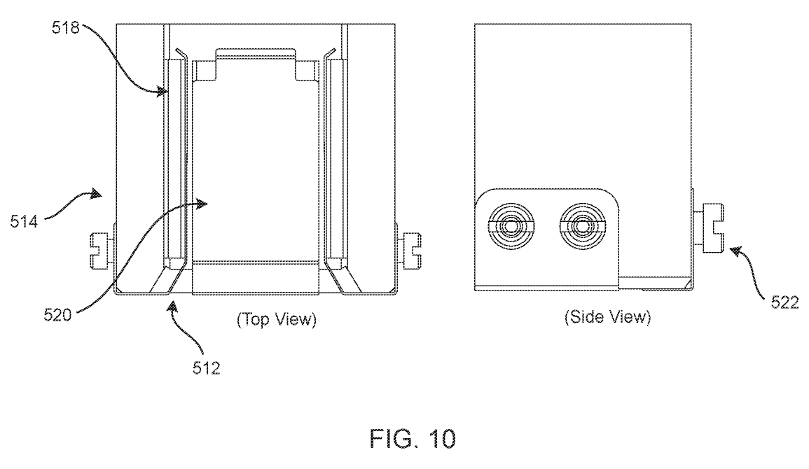

Referring to FIG. 10, again, each protective plate 520 is retained via the plurality of retention screws 522 disposed on an outboard side of the associated extension portion 512,514. These retention screws 522 provide each protective plate with a small degree of outboard play or movement, on the order of 1mm. This allows the front end 102 and IC-TROSA 104 of the plug 100 to be inserted between the protective plates 520 relatively easily, but while maintaining a desired thermal contact pressure through the protective plates 520 and GoF pads 518. Before the plug 100 is inserted, the protective plates 520 surrounding the extension portions 512,514 and the GoF pads 518 are biased inwards, away from the retention screws 522, by the non-compressed GoF pads 518.

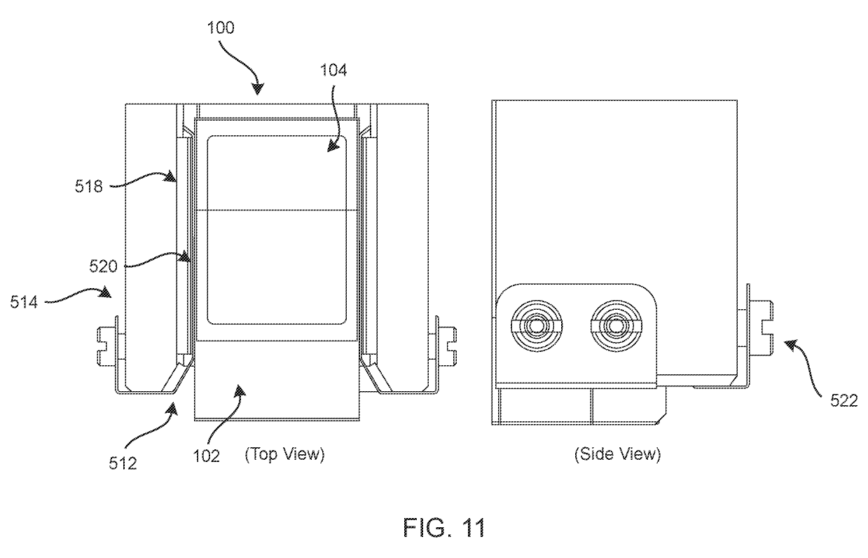

Referring to FIG. 11, again, each protective plate 520 is retained via the plurality of retention screws 522 disposed on an outboard side of the associated extension portion 512,514. These retention screws 522 provide each protective plate with a small degree of outboard play or movement, on the order of 1mm. This allows the front end 102 and IC-TROSA 104 of the plug 100 to be inserted between the protective plates 520 relatively easily, but while maintaining a desired thermal contact pressure through the protective plates 520 and GoF pads 518. After the plug 100 is inserted, the protective plates 520 surrounding the extension portions 512,514 and the GoF pads 518 are biased outwards, towards from the retention screws 522, by the plug 100. The GoF pads 518 are now compressed accordingly.

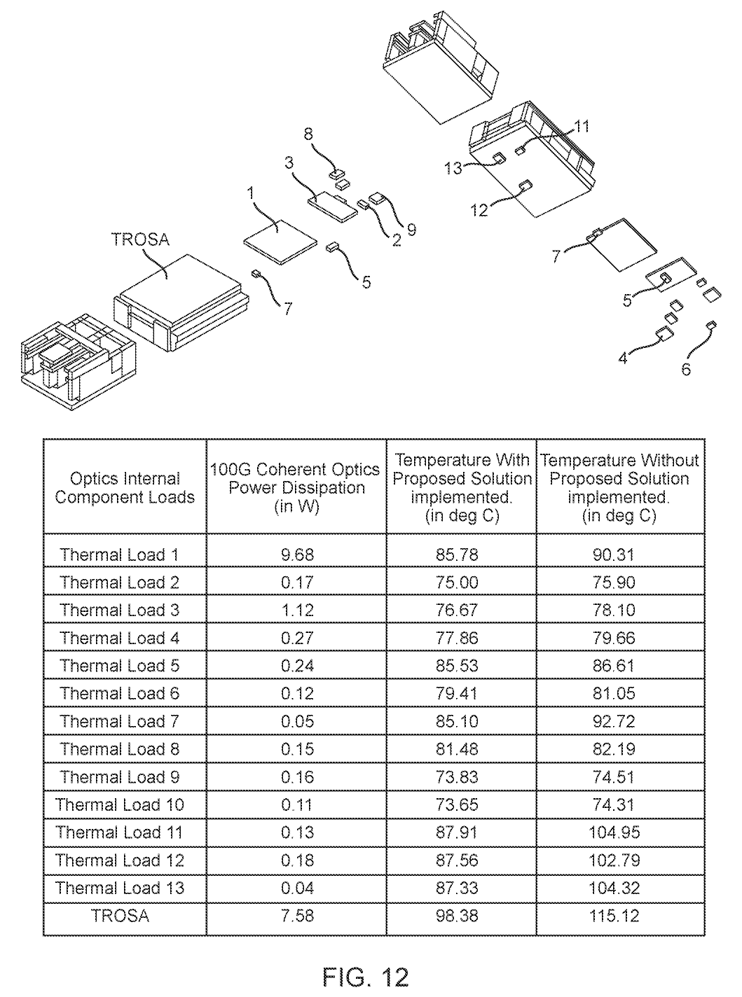

FIG. 12 illustrates an example of the thermal performance of the heat spreader plate 500 and adjustable heat sink holder assembly 400 of the present disclosure via the temperatures provided on an associated plug 100 for 100G coherent optics power dissipation. The IC-TROSA 104 is a significant thermal load and a temperature improvement of about 17°C is observed when proposed solution is used, as well as a temperature improvement of about 5°C for the main DSP load.

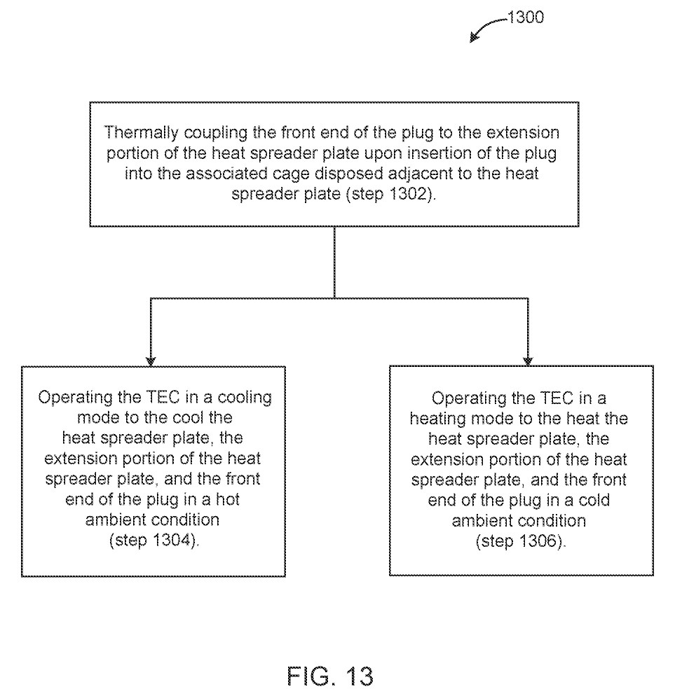

FIG. 13 illustrates an embodiment of the plug cooling/heating method 1300 of the present disclosure in an outdoor conduction cooled network system. The method 1300 includes thermally coupling the front end of the plug to the extension portion of the heat spreader plate upon insertion of the plug into the associated cage disposed adjacent to the heat spreader plate (step 1302) and, alternatively, operating the TEC in a cooling mode to the cool the heat spreader plate, the extension portion of the heat spreader plate, and the front end of the plug in a hot ambient condition (step 1304) or operating the TEC in a heating mode to the heat the heat spreader plate, the extension portion of the heat spreader plate, and the front end of the plug in a cold ambient condition (step 1306).

Although the present disclosure is illustrated and described with reference to specific embodiments and examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A heat sink assembly comprising
a heat spreader plate adapted to be disposed adjacent to and in thermal communication with a plug device, wherein the heat spreader plate comprises
a main body portion adapted to be disposed adjacent to a central portion of the plug device and thermally condition the central portion of the plug device, and
an extension portion adapted to be disposed adjacent to a front end portion of the plug device and thermally condition the front end portion of the plug device.

2. The heat sink assembly of claim 1, further comprising a thermoelectric cooler disposed adjacent to and in thermal communication with the heat spreader plate and adapted to be operated in one of a cooling mode and a heating mode.

3. The heat sink assembly of claim 1, further comprising a vapor chamber defined by the heat spreader plate.

4. The heat sink assembly of claim 1, wherein the extension portion of the heat spreader plate comprises a lower extension portion adapted to be disposed adjacent to a lower front end portion of the plug device.

5. The heat sink assembly of claim 4, wherein the lower extension portion comprises a thermally conductive compressible pad covered by a protective plate that are collectively adapted to contact the lower front end portion of the plug device.

6. The heat sink assembly of claim 1, wherein the extension portion of the heat spreader plate comprises side extension portions adapted to be disposed adjacent to side front end portions of the plug device.

7. The heat sink assembly of claim 6, wherein each of the side extension portions comprises a thermally conductive compressible pad covered by a protective plate that are collectively adapted to contact the side front end portions of the plug device.

8. The heat sink assembly of claim 1, wherein the plug device is a high power optics plug device, the central portion of the high power optics plug device comprises digital signal processor hardware, and the front end portion of the high power optics plug device comprises an integrated coherent transmit-receive optical sub-assembly.

9. The heat sink assembly of claim 1, wherein the heat spreader plate and the plug device are disposed in a sealed housing of an outdoor conduction cooled network system.

10. A network system comprising
a sealed housing, and
a heat spreader plate disposed within the sealed housing and adapted to be disposed adjacent to and in thermal communication with a plug device also disposed within the sealed housing, wherein the heat spreader plate comprises
a main body portion adapted to be disposed adjacent to a central portion of the plug device and thermally condition the central portion of the plug device, and
an extension portion adapted to be disposed adjacent to a front end portion of the plug device and thermally condition the front end portion of the plug device.

11. The network system of claim 10, further comprising a thermoelectric cooler disposed adjacent to and in thermal communication with the heat spreader plate and adapted to be operated in one of a cooling mode and a heating mode.

12. The network system of claim 10, further comprising a vapor chamber defined by the heat spreader plate.

13. The network system of claim 10, wherein the extension portion of the heat spreader plate comprises a lower extension portion adapted to be disposed adjacent to a lower front end portion of the plug device.

14. The network system of claim 13, wherein the lower extension portion comprises a thermally conductive compressible pad covered by a protective plate that are collectively adapted to contact the lower front end portion of the plug device.

15. The network system of claim 10, wherein the extension portion of the heat spreader plate comprises side extension portions adapted to be disposed adjacent to side front end portions of the plug device.

16. The network system of claim 15, wherein each of the side extension portions comprises a thermally conductive compressible pad covered by a protective plate that are collectively adapted to contact the side front end portions of the plug device.

17. The network system of claim 10, wherein the plug device is a high power optics plug device, the central portion of the high power optics plug device comprises digital signal processor hardware, and the front end portion of the high power optics plug device comprises an integrated coherent transmit-receive optical sub-assembly.

18. The network system of claim 10, wherein the heat spreader plate and the plug device are disposed in the sealed housing of an outdoor conduction cooled network system.

19. A heat sink method comprising
providing a heat spreader plate disposed adjacent to and in thermal communication with a plug device, wherein the heat spreader plate comprises
a main body portion disposed adjacent to a central portion of the plug device and thermally conditioning the central portion of the plug device, and
an extension portion disposed adjacent to a front end portion of the plug device and thermally conditioning the front end portion of the plug device, and
providing a thermoelectric cooler disposed adjacent to and in thermal communication with the heat spreader plate.

20. The heat sink method of claim 19, further comprising operating the thermoelectric cooler in one of a cooling mode to cool the central portion of the plug device and the front end portion of the plug device and a heating mode to heat the central portion of the plug device and the front end portion of the plug device.
